(19) United States
(12) Patent Application Publication
(10) Pub. No.: US 2026/0291186 A1
(43) Pub. Date: Sep. 24, 2026

(54) PORTABLE HANDHELD RAPID STATE DETECTION DEVICE FOR GIS APPARATUS

(71) Applicant: CSGES OPERATION MANAGEMENT BRANCH COMPANY, Guangzhou (CN)

(72) Inventors: Menglong HOU, Guangzhou (CN); Jingyu WANG, Guangzhou (CN); Guodong XIE, Guangzhou (CN); Wenyu FENG, Guangzhou (CN); Donglu LI, Guangzhou (CN); Xin LIU, Guangzhou (CN); Yongjun LIN, Guangzhou (CN)

(73) Assignee: CSGES OPERATION MANAGEMENT BRANCH COMPANY, Guangzhou (CN)

(21) Appl. No.: 18/868,923

(22) PCT Filed: Dec. 6, 2023
(86) PCT No.: PCT/CN2023/136725

§ 371 Date: Jun. 1, 2026

(30) Foreign Application Priority Data
Apr. 24, 2023 (CN) 202310453107.0

(51) Int. Cl. H02B 13/035; H04N 23/50; H04N 23/56

(52) U.S. Cl. CPC H02B 13/0356; H04N 23/555; H04N 23/56

(57) ABSTRACT

The present invention broadly comprises a detection camera, a GIS test tablet computer, an image analysis module, a data transmission module, and a fixing and limiting module, wherein an end of the detection camera protrudes to form a monitoring protrusion; and the monitoring protrusion is embedded into a knife switch observation hole, and the camera lens and the light supplement lamp are respectively embedded into a light supplement hole and a camera hole in the knife switch observation hole. With the present invention, dynamic positional changes of a knife switch can be accurately and quickly determined, and the position of a GIS knife switch can be quickly confirmed, thereby facilitating execution of an isolation operation and avoiding problems of inaccurate opening and closing indications of the knife switch of the GIS apparatus and being time-consuming in terms of confirming opening and closing positions.

### TECHNICAL FIELD

The present disclosure belongs to the technical field of detection devices, in particular to a portable and handheld device for rapidly detecting a state of GIS equipment.

### BACKGROUND

Gas insulated switchgear (GIS) equipment refers to “gas-insulated and metal-enclosed switchgear”, which is mainly composed of a circuit breaker, a disconnector, an earthing switch, a transformer, an arrester, a busbar, a connector, and an outlet terminal. GIS is widely used not only in high-voltage and extra-high-voltage fields, but also in ultra-high-voltage fields. Compared with conventional open substations, GIS has the advantages of compact structure, small footprint, high reliability, flexible configuration, convenient installation, strong safety, strong environmental adaptability, and small maintenance workload.

GIS knife switch devices used in some existing power storage stations are located in closed chambers filled with inert gas, which have advantages such as compact structure, flexibility, maintenance-free and are not affected by external environmental conditions. However, compared with conventional open knife switch devices, GIS knife switch devices are not intuitive, i.e., it is impossible to directly observe the contact state of GIS knife switch contact to identify whether the GIS knife switch contact is opened or closed in place. Once the contact is not opened or closed in place, the consequences are unimaginable. Therefore, it is particularly important to quickly and accurately identify whether the GIS knife switch is closed in place in the knife switch operations.

The observation for GIS knife switch device is often carried out through the knife switch observation window set outside the closed chamber. The knife switch observation window is usually set at a relatively high position of the closed device, and a continuous observation is required until the power is exhausted. The detection operation can be realized by embedding the camera used for detection on the knife switch observation window after the staff moves to the position of the knife switch observation window through the climbing frame. However, the combination of the camera used for detection and the knife switch observation window depends on the friction generated by the embeddings to hold the camera in place, and thus the combination may be unstable during the long-term detection operation, or even drop of the camera or collision therebetween may occur, resulting in camera damage and thus affecting the normal detection operation.

### SUMMARY

In order to address the above technical problems to make up for the deficiencies in the existing technology, the present disclosure provides a portable and handheld device for rapidly detecting a state of GIS equipment.

The present disclosure adopts the following technical solutions to address the above technical problems: a portable and handheld device for rapidly detecting a state of GIS equipment includes: a detection camera, a GIS detection tablet, an image analysis module, a data transmission module, and a fixing and limiting module. An end of the detection camera protrudes to form a monitoring bump, the monitoring bump is provided with a camera lens and a fill light. The monitoring bump is embedded into a knife switch observation hole, the camera lens and the fill light lamp are embedded into a camera hole and a fill light hole of the knife switch observation hole, respectively. A protective cover is sleeved on an outside of the monitoring bump.

The data transmission module is configured to transmit an image information captured by the detection camera to the GIS detection tablet. The image analysis module is mounted on the GIS detection tablet, and is configured to analyze the image information and determine a position change of a knife switch to be detected.

The fixing and limiting module is configured to assist the detection camera to be fixed in the knife switch observation hole. The fixing and limiting module includes a limiting sleeve which is cylindrical and wraps an outside of the detection camera.

An end of the limiting sleeve is provided with a limiting snap ring wrapping around the monitoring bump, an outer surface of the limiting snap ring is provided with a fixing magnet, and an outer ring surface of the limiting snap ring is made of an elastic material.

Preferably, a sliding groove is provided on an inner sidewall of the limiting sleeve adjacent to the limiting snap ring. A pressing ring is provided on an annular opening portion of the limiting sleeve adjacent to the limiting snap ring. A vertical cross-section of the pressing ring is in an L-shape, one end of the pressing ring is embedded into the sliding groove and is slidably connected to the sliding groove, and the other end thereof is in contact with an outer surface of the limiting snap ring. A region surrounded between the pressing ring and the limiting snap ring defines a limiting cavity, an outer ring portion of the limiting snap ring is hollow and defines a fixing cavity, and the limiting cavity is in communication with the fixing cavity.

Preferably, a limiting airbag is provided in the limiting cavity. The limiting airbag is annular, the limiting airbag is in communication with an interior of the fixing cavity via a connecting pipe, and a control valve is provided in a middle portion of the connecting pipe.

Preferably, limiting bumps are uniformly arranged on an outer surface of a side wall of the fixing cavity, and an end of each the limiting bump is inclined in a direction away from the camera hole.

Preferably, a suction hole is provided on a portion of the pressing ring facing an end surface of the knife switch observation hole, and the suction hole is in communication with the fixing cavity.

Preferably, an outer surface of the suction hole provided with a sealing ring made of an elastic material.

Preferably, a fixing magnet is provided on the outer surface of the limiting snap ring and is located in an interior region of the limiting cavity. The fixing magnet is distributed annularly around a central axis of the limiting sleeve.

Preferably, a fixing claw is provided at an end of the limiting sleeve and is located outside the pressing ring. The fixing claw is made of an elastic material.

Preferably, anti-slip blocks are uniformly arranged on an inner surface of the fixing claw, and each anti-slip block has a sharp end and is made of a rubber material.

Preferably, a cleaning rod is provided at an end of the limiting sleeve away from the limiting snap ring, and a cleaning block is provided at an end of the cleaning rod. The cleaning block has a circular plate structure and is wrapped by a cleaning sleeve around an outer surface thereof.

The present disclosure has the following beneficial effects:
1. In a portable and handheld device for rapidly detecting a state of GIS equipment according to the present disclosure, the elastic part of the outer ring of the limiting snap ring is in contact with the inner wall surface of the knife switch observation hole, increasing the relative friction therebetween, so that the limiting snap ring is embedded into the knife switch observation hole more stably. Moreover, after the limiting snap ring is embedded, the fixing magnet located on the outer surface of the limiting snap ring and the inner wall of the knife switch observation hole made of iron attract each other, so that the limiting snap ring drives the monitoring bump and even the whole detection camera to be more stably combined with the knife switch observation hole during the monitoring process, thereby providing a relatively stable capturing platform for the opening-closing detection operation of the knife switch equipment and ensuring the smooth progress of normal monitoring operations.
2. The portable and handheld device for rapidly detecting the state of GIS equipment according to the present disclosure can accurately and quickly determine the whole process of dynamic change of the knife switch position, so that the confirmation time of the GIS knife switch position can reach within 15 seconds, facilitating to perform the isolation operation and avoiding the issue of inaccurate opening and closing indications of the GIS knife switch device and time-consuming confirmation of the opening and closing position.

### BRIEF DESCRIPTION OF THE DRAWINGS

The present disclosure will be further described in conjunction with the accompanying drawings.

FIG. 1 is a perspective view of the present disclosure.

FIG. 2 is a partially enlarged view of position A in FIG. 1.

FIG. 3 is a partial schematic view of a knife switch observation hole applied to the present disclosure.

FIG. 4 is a perspective view of the present disclosure.

FIG. 5 is a perspective view of a pressing ring according to the present disclosure.

FIG. 6 is a half-sectional view of the present disclosure in combination with a knife switch observation hole.

FIG. 7 is a partially enlarged view of position B in FIG. 6.

FIG. 8 is a perspective view of a detection camera according to the present disclosure.

FIG. 9 shows a working flowchart after starting of the present disclosure.

In figures:

1: detection camera, 11: monitoring bump, 111: camera lens, 112: fill light, 113: protective cover, 2: fixing and limiting module, 211: sliding groove, 21: limiting sleeve, 22: limiting snap ring, 221: fixing cavity, 222: limiting bump, 23: fixing magnet, 24: pressing ring, 241: limiting cavity, 242: suction hole, 243: sealing ring, 25: limiting airbag, 251: connecting pipe, 26: fixing claw, 261: anti-slip block, 27: cleaning rod, 271: cleaning block 272: cleaning sleeve, 3: knife switch observation hole, 31: fill light hole, 32: camera hole.

### DETAILED DESCRIPTION

The technical solutions in the embodiments of the present disclosure will be clearly and thoroughly described with reference to the accompanying drawings in the embodiments of the present disclosure. Apparently, the described embodiments are only some of, not all of the embodiments of the present disclosure. Based on the embodiments in the present disclosure, all other embodiments obtained by those skilled in the art without creative effort should fall within the scope of the present disclosure.

### Embodiment 1

A portable and handheld device for rapidly detecting a state of GIS equipment is provided. GIS knife switch devices used in some existing power storage stations are provided in closed chambers filled with inert gas, which have advantages such as compact structure, flexibility, maintenance-free and are not affected by external environmental conditions. However, compared with conventional open knife switch devices, GIS knife switch devices are not intuitive, i.e., it is impossible to directly observe the contact state of GIS knife switch contact to identify whether the GIS knife switch contact is opened or closed in place. Once the contact is not opened or closed in place, the consequences are unimaginable. Therefore, it is particularly important to quickly and accurately identify whether the GIS knife switch is closed in place in the knife switch operations.

The observation for GIS knife switch device is usually carried out through the knife switch observation window set outside the closed chamber. The knife switch observation window is usually set at a relatively high position of the closed device, and a continuous observation is required until the power is exhausted. The detection operation can be realized by embedding the camera used for detection on the knife switch observation window after the staff moves to the position of the knife switch observation window through the climbing frame. However, the combination of the camera used for detection and the knife switch observation window depends on the friction generated by the embeddings to hold the camera in place, and thus the combination may be unstable during the long-term detection operation, or even drop of the camera or collision therebetween may occur, resulting in camera damage and thus affecting the normal detection operation.

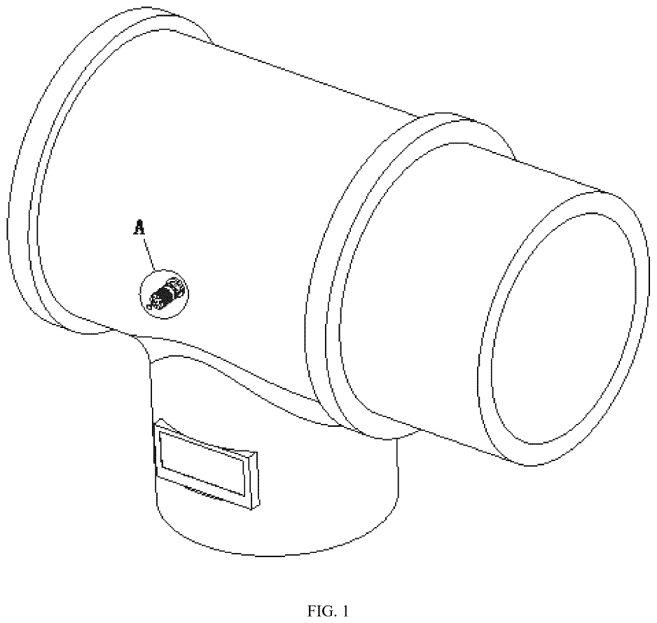

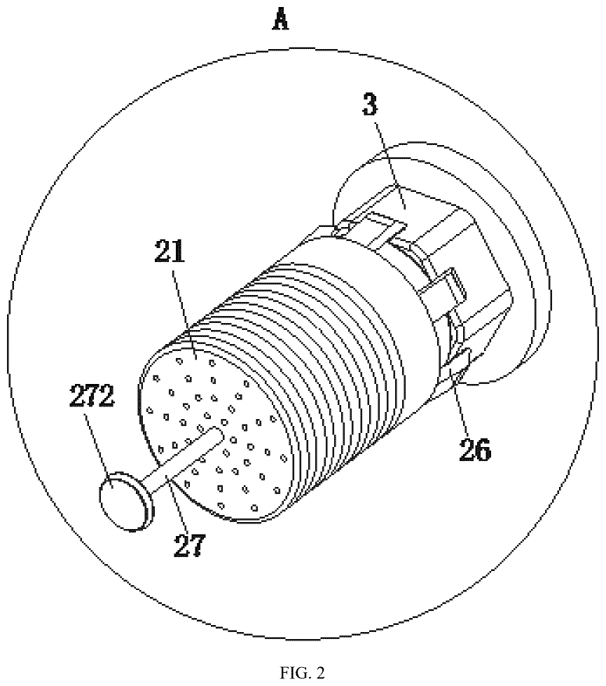

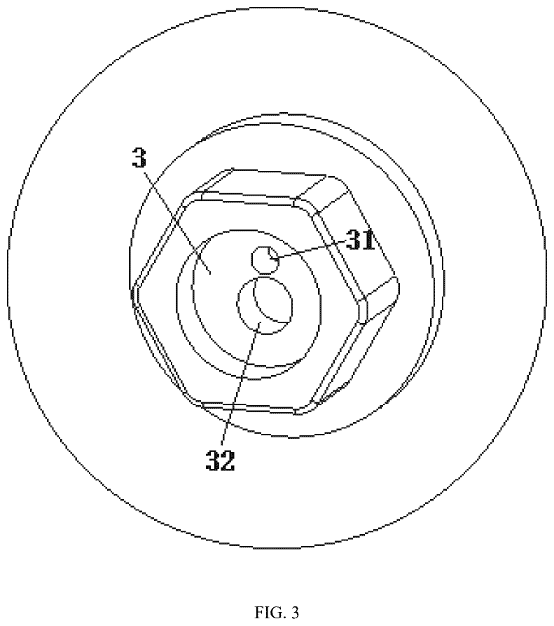

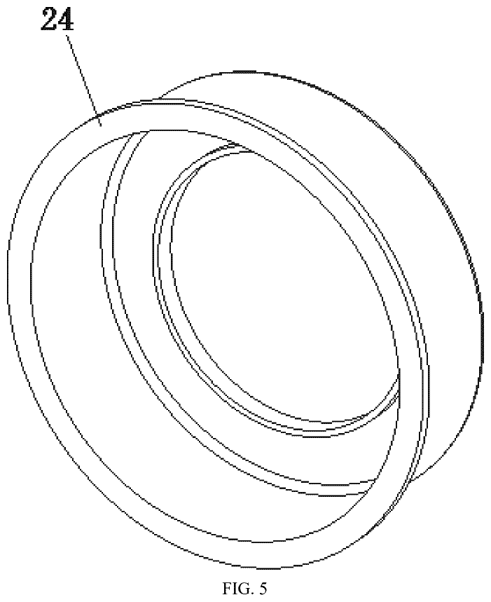

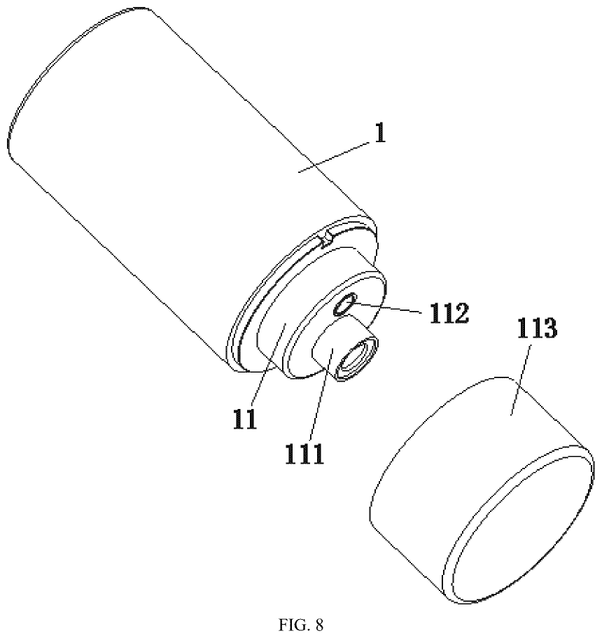

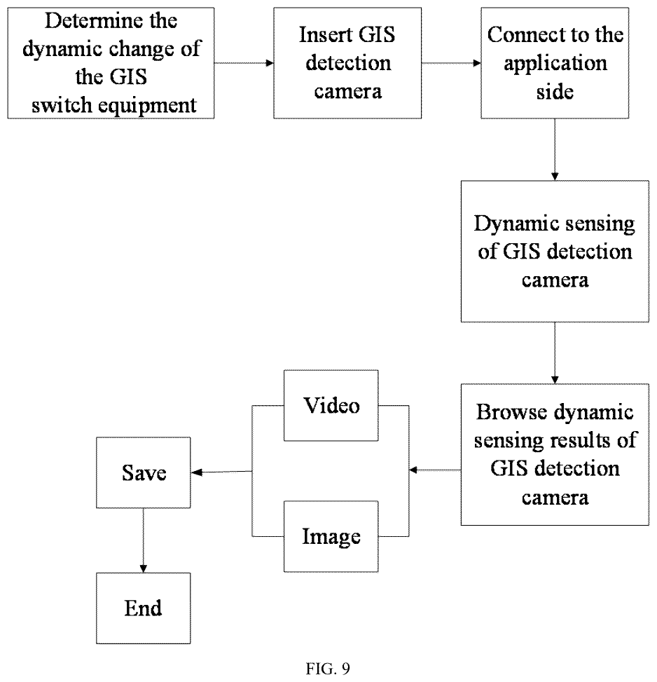

In order to effectively address the above issues, the present disclosure provides a portable and handheld device for rapidly detecting a state of GIS equipment, as shown in FIGS. 1 to 9 in the drawings of the specification, which includes a detection camera 1, a GIS detection tablet, an image analysis module, a data transmission module, and a fixing and limiting module 2. An end of the detection camera 1 protrudes to form a monitoring bump 11. A camera lens 111 and a fill light 112 are provided on the monitoring bump 11. The detection camera 1 adopts a dedicated GIS camera as a sensing end. The detection camera 1 aims at an application side, i.e., the location of the GIS knife switch device.

The end of the detection camera 1 is provided with the camera lens 111 and the fill light 112. A protective cover 113 is sleeved on an outside of the monitoring bump 11 to protect the camera lens 111 and the fill light 112 therein, and the protective cover 113 can be removed during the operation. A knife switch observation hole 3 is provided on an outside of the closed chamber where the GIS knife switch device is located, as the application side. The knife switch observation hole 3 is provided with a fill light hole 31 and a camera hole 32. The fill light hole 31 and the camera hole 32 are in communication with an inside of the closed chamber, and a sealing glass is provided on the joint portion, so that the detection operation can be performed while ensuring the sealing of the interior of the closed chamber. When the monitoring bump 11 is embedded in the knife switch observation hole 3, the camera lens 111 and the fill light 112 can be embedded in the camera hole 32 and the fill light hole 31 of the knife switch observation hole 3, respectively, so as to observe and detect the GIS knife switch device in the closed chamber through the sealing glass.

The camera lens 111 can shoot the working state of the GIS knife switch device in the closed chamber through the knife switch observation hole 3. An LED light is selected as the fill light 112. When turned on, the fill light 112 can illuminate the interior of the closed chamber through the sealing glass, thus creating a working environment with good brightness inside the closed chamber, which is convenient for shooting operations.

The other end of the detection camera 1 is provided with a data jack, which can be connected to a data wire for wired data transmission, so as to more stably transmit the captured video data, while charging the internal battery. A control button is further mounted on the detection camera 1, which is responsible for adjusting the brightness of the fill light 112, starting and closing the detection camera 1, and other functions, so that the operator can facilitate adjustments according to the use environment, improving the applicability of the detection camera 1 to the working environment.

The data transmission module is configured to transmit the image information captured by the detection camera 1 to the GIS detection tablet. The operator holds the GIS detection tablet for observation under the equipment. An image analysis module is mounted on the GIS detection tablet to analyze the transmitted image information and determine the position change of the knife switch to be detected.

The fixing and limiting module 2 is configured to assist the detection camera 1 to be fixed in the knife switch observation hole 3. The fixing and limiting module 2 includes a limiting sleeve 21 which is cylindrical and wraps around the outside of the detection camera 1. The side wall of the limiting sleeve 21 can be made of materials with electromagnetic shielding effects to reduce the adverse effects of the high electromagnetic environment on the normal internal operation of the detection camera 1, and to protect the detection camera 1 to reduce the damage in case of collisions that occur during the installation process.

An end of the detection camera 1 away from the knife switch observation hole 3 is evenly provided with ventilation holes, so that the internal and external environments of the limiting sleeve 21 are in communication with each other. The exchange of air plays a role in cooling the detection camera 1. Moreover, the end of the detection camera 1 away from the knife switch observation hole 3 is made of non-electromagnetic shielding material, and the transmitting end of the detection camera 1 is also provided here, which is convenient to wirelessly transmit the image signal through the ventilation holes to the GIS detection tablet.

An end of the limiting sleeve 21 is provided with a limiting snap ring 22 wrapping around the monitoring bump 11. An end of the limiting snap ring 22 protrudes from the end of the monitoring bump 11. When embedded in the knife switch observation hole 3, the limiting snap ring 22 is embedded in the knife switch observation hole 3 prior to the end of the monitoring bump 11. An outer surface of the limiting snap ring 22 is provided with a fixing magnet 23 and the limiting snap ring 22. An inner ring surface of the limiting snap ring 22 is made of hard material to protect the monitoring bump 11, and an outer ring surface of the limiting snap ring 22 is made of elastic material, such as rubber material.

Specific workflow is as follows: when the GIS knife switch of important power storage equipment located on the power storage station needs to be closed or opened, the operator moves to the location of the knife switch observation hole 3 on the closed chamber by means of a climbing frame, a ladder, or other tools, and then holds the limiting sleeve 21 and makes the limiting snap ring 22 protruding from the end of the limiting sleeve 21 to be aligned with and embedded in the knife switch observation hole 3, so that the monitoring bump 11 on the monitoring bump 11 is embedded in the knife switch observation hole 3. The fill light 112 and the camera lens 111 on the monitoring bump 11 are aligned with and embedded in the fill light hole 31 and the camera hole 32 respectively, thereby facilitating the later detection operation.

During the embedding process, the end of the limiting snap ring 22 sleeved on the outer surface of the monitoring bump 11 is embedded into the knife switch observation hole 3 prior to the monitoring bump 11, and is in contact with the inner wall surface of the knife switch observation hole 3. The limiting snap ring 22 is then embedded along the inner extension direction of the knife switch observation hole 3, such that the monitoring bump 11 is subjected to limit action before embedding, and thus embedded along a stable motion trajectory.

Similarly, when the detection camera 1 is removed, the limiting snap ring 22 has not yet completely slid out, while the monitoring bump 11 has already separated from the knife switch observation hole 3 along the stable sliding trajectory. As such, the movement of the monitoring bump 11 component along the stable and fixed motion trajectory can reduce lateral sway of the monitoring bump 11 in the knife switch observation hole 3 during the manual embedding process, which is caused by insufficiently tight limit in embedding or removal operations, and results in that the embedded monitoring bump 11, the upper fill light 112, and the camera lens 111 collide with the inner wall of the knife switch observation hole 3 due to the sway. As a result, the damage of the monitoring bump 11 and the upper fill light 112, and the camera lens 111 due to collision with the inner wall of the knife switch observation hole 3 can be effectively reduced.

Further, in the process of embedding installation, the elastic part of the outer ring of the limiting snap ring 22 is in contact with the inner wall surface of the knife switch observation hole 3, increasing the relative friction therebetween, so that the limiting snap ring 22 is embedded into the knife switch observation hole 3 more stably. Moreover, after the limiting snap ring 22 is embedded, the fixing magnet 23 located on the outer surface of the limiting snap ring 22 and the inner wall of the knife switch observation hole 3 made of iron are attracted to each other, so that the limiting snap ring 22 drives the monitoring bump 11 and even the whole detection camera 1 to be more stably combined with the knife switch observation hole 3 during the monitoring process, thereby providing a relatively stable capturing platform for the opening-closing detection operation of the knife switch equipment and ensuring the smooth progress of normal monitoring operations.

After the detection camera 1 is mounted, the fill light 112 is turned on, and the light passes through the corresponding sealing glass to illuminate the interior of the closed chamber. The camera lens 111 then captures the state in the closed chamber through the sealing glass on the camera hole 32. In the closing process of the knife switch, the iron rod-shaped movable contact sticks out to contact the static contact at the opposite position to complete the closing and energization. During this process, the detection camera 1 captures images during the opening process and transmits the images to the GIS detection tablet, facilitating the operator to watch, while the image analysis module mounted on the GIS detection tablet can analyze the images.

Specifically, the image analysis module GIS knife switch state intelligent recognition application (APP) can automatically recognize and display the opening and closing states of GIS knife switch through AI algorithms during operation, so that the recognition of the opening and closing states of GIS knife switch can be upgraded from confirmation by user through eyes to system automatic recognition, improving recognition accuracy and user work efficiency by 80% or more.

In order to detect whether the knife switch is closed in place in real time, deep learning and semantic segmentation techniques can be used in combination with multi-segment exposure algorithms. The semantic segmentation algorithm will use NCNN quantization, and allow the deep learning segmentation algorithm to be deployed on the GIS detection tablet through a large number of pruning and model compression techniques.

The segmentation model uses the latest Pyramid Scene Parsing Network and has been optimized to realize a minimum detection accuracy of 10% of the length of the knife switch. The detection speed is 2 seconds per time (2s/time).

The present disclosure further supports the AI recognition function when previewing the video in real time to detect whether the knife switch is damaged in real time. After the knife switch is in place, the edge features of the knife switch are extracted by deep learning feature extraction technology. After the deep learning edge extraction, the distribution of all line segments is statistically calculated using the differential slope statistical algorithm to determine whether the edge is damaged so as to realize the detection purpose. The minimum damage area for detection is 5% of the visual field area of the knife switch, and the detection time is 2s/time. Once the damage is found, the alarm is called in time to inform the observer to pay attention and stay away, and inform the maintenance personnel to cut off the power for maintenance of the equipment.

The AI recognition function is supported when previewing the video in real time to detect whether blockage caused by a foreign object in the slot occurs in real time to prevent the foreign object from blocking and damaging the knife switch before the closing. This detection uses HSV color extraction algorithm to extract the color of the background as a template. During the detection, HSV algorithm is used again to extract the color of the real-time detected image to compare with the template and obtain a difference energy image. At last, the abnormal area is extracted by adaptive binarization technology. In this algorithm, the minimum foreign object detection diameter is 20% of the length of the knife switch, and the detection time is 1 s/time.

Through the algorithm, the color of the highlight surface of the sticking portion of the iron rod-shaped movable contact and the protective protruding surface plastic portion can be identified. The sticking length of the iron rod-shaped movable contact and the position of entering the static contact can be determined according to the position change of the above color parts during the closing process, so as to accurately determine whether the closing is in place.

The present disclosure can stably capture the working process of the GIS knife switch device in the closed chamber, and accurately and quickly determine the whole process of dynamic change of the knife switch position, so that the confirmation time of the GIS knife switch position can be within 15 seconds, facilitating to perform the isolation operation and avoiding the issue of inaccurate opening and closing indications of the GIS knife switch device and time-consuming confirmation of the opening and closing position.

### Embodiment 2

On the basis of embodiment 1, as shown in FIGS. 1 to 8, a sliding groove 211 is provided on an inner sidewall of the limiting sleeve 21 adjacent to the limiting snap ring 22, and a pressing ring 24 is mounted on an annular opening portion of a cavity sleeve 241 adjacent to the limiting snap ring 22. A vertical cross-section of the pressing ring 24 is in an L-shape. One end of the pressing ring 24 is embedded into the sliding groove 211 and is slidably connected to the sliding groove 211 through a return spring, and the other end of the pressing ring 24 is in contact with an outer surface of the limiting snap ring 22. A region surrounded between the pressing ring 24 and the limiting snap ring 22 defines a limiting cavity 241, an outer ring portion of the limiting snap ring 22 is hollow and defines a fixing cavity 221. The limiting cavity 241 is in communication with the fixing cavity 221.

Specific workflow is as follows: on the basis of the specific workflow in embodiment 1, in order to ensure the convenience of installation and removal of the detection camera 1 during work, the diameter of the outer ring surface of the limiting snap ring 22 can be selected to be less than the inner diameter of the knife switch observation hole 3. In this way, after the limiting snap ring 22 is embedded into the knife switch observation hole 3 with the monitoring bump 11, a gap is maintained between the outer ring surface of the limiting snap ring 22 and the inner wall of the knife switch observation hole 3;

After that, the operator can push the limiting sleeve 21, so that the limiting sleeve is further embedded deeply into the knife switch observation hole 3. The limiting sleeve 21 is then pressed against the pressing ring 24 on the end surface of the knife switch observation hole 3. The pressing ring 24 slides under pressure, and the end thereof embedded in the sliding groove 211 further presses the return spring to be further embedded into the sliding groove 211, so that the internal space of the limiting cavity 241 is reduced, the air inside the limiting cavity 241 flows into the fixing cavity 221 at the outer ring of the limiting snap ring 22. As such, the air pressure inside the fixing cavity 221 increases and expands, the outer ring portion of the limiting snap ring 22 corresponding to the fixing cavity 221 is in close contact with the inner wall surface of the knife switch observation hole 3 due to expansion, which increases the relative friction between the limiting snap ring 22 and the inner wall of the knife switch observation hole 3, so that the limiting sleeve 21 can be mounted more stably.

Further, a control valve is provided at a joint portion between the limiting cavity 241 and the fixing cavity 221 to control the airflow into the fixing cavity 221 to realize the expansion of the fixing cavity 221. After the limiting snap ring 22 and the knife switch observation hole 3 are engaged with each other tightly, the control valve is activated to block the communication parts to ensure the inflation and expansion degree of the fixing cavity 221, allowing the limiting sleeve 21 to be embedded more stably. The detection camera 1 and the knife switch observation hole 3 remain relatively stable during the monitoring operation, so that the monitoring operation for the knife switch equipment can be performed smoothly.

Further, when removal is required, only the control valve needs to be controlled and opened from the outside, so that the airflow located in the fixing cavity 221 returns to the interior of the limiting cavity 241. On the one hand, the relative friction between the limiting snap ring 22 and the inner wall of the knife switch observation hole 3 is reduced. On the other hand, the air pressure inside the limiting cavity 241 is increased to push the pressing ring 24 to move in a direction away from the knife switch observation hole 3, and drive the monitoring bump 11 to slide away from the knife switch observation hole 3, so that the detection camera 1 can be removed more easily, avoiding damage to the detection camera 1 due to manual rough pulling out. As such, the mounting and removing of the detection camera 1 relative to the knife switch observation hole 3 can be more automatic and convenient, reducing the problems caused by manual operation errors during the installation and removal.

### Embodiment 3

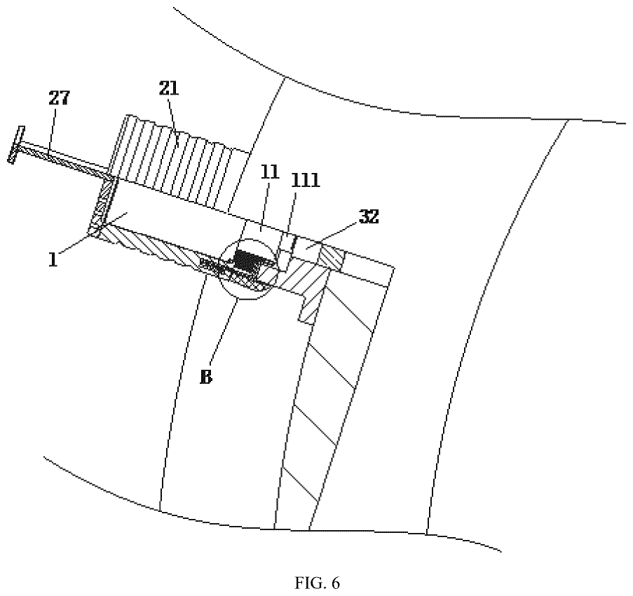

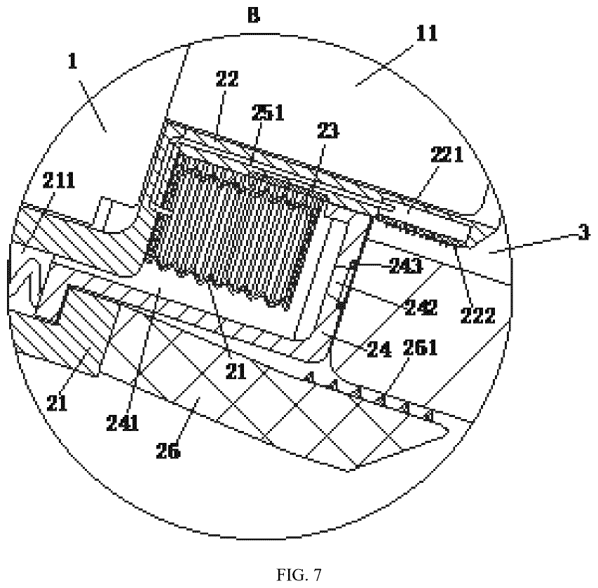

On the basis of embodiment 2, as shown in FIGS. 6 and 7, a limiting airbag 25 is provided in the limiting cavity 241. The limiting airbag 25 is annular and is in communication with an interior of the fixing cavity 221 via a connecting pipe 251. A control valve is provided in a middle portion of the connecting pipe 251. Limiting bumps 222 are uniformly arranged on an outer surface of a side wall of the fixing cavity 221. Specifically, the limiting bumps 222 are uniformly distributed on the outer surface of the limiting snap ring 22 corresponding to the fixing cavity 221, and can be made of an elastic material such as rubber. An end of the limiting bump 222 is inclined in a direction away from the camera hole 32.

Specific workflow is as follow: on the basis of the specific workflow in embodiment 2, in order to further ensure that the airflow inside the limiting cavity 241 smoothly flows into the fixing cavity 221, a limiting airbag 25 is provided inside the limiting cavity 241. When sliding, the pressing ring 24 contacts and squeezes the limiting airbag 25, so that the limiting airbag 25 is compressed to input airflow into the fixing cavity 221 through the connecting pipe 251 in communication with the fixing cavity 221 to control the internal expansion of the fixing cavity 221, thus fixing the limiting snap ring 22. In this way, through the limiting airbag 25 with better sealing, it is avoided that the airflow inside the limiting cavity 241 flows out through the connection gap of the pressing ring 24 due to the pressure, thus affecting the control of air pressure.

Further, in the removing process, the control valve is closed through an external controller, so that the airflow inside the fixing cavity 221 reversely enters the limiting airbag 25 inside the limiting cavity 241 through the connecting pipe 251, so that the limiting airbag 25 expands and presses the pressing ring 24, and the pressing ring 24 pushes the end surface of the knife switch observation hole 3. This reverse action causes the end of the detection camera to slide out, which facilitates the separation between the detection camera 1 and the knife switch observation hole 3. Since the sealing performance of the limiting airbag 25 is good, the limiting airbag 25 can be filled with liquid therein. The liquid has a small compressibility. After the liquid enters the fixing cavity 221, the fixing cavity 221 expands more obviously, thereby allowing the limiting snap ring 22 to be embedded into the knife switch observation hole 3 more tightly. The detection camera 1 and the knife switch observation hole 3 are combined more stably during the monitoring operation, so that the monitoring operation can be carried out more smoothly.

Further, the limiting bump 222 is uniformly arranged on the outer surface of the limiting snap ring 22 corresponding to the fixing cavity 221, and the end thereof is inclined. As such, after the fixing cavity 221 is expanded, the end of the limiting bump 222 is in contact with the inner surface of the knife switch observation hole 3 under the expansion action, and is combined with the inner surface more tightly, further ensuring the stability of the detection camera 1 during the installation process, and thereby ensuring the smooth progress of the monitoring operation.

### Embodiment 4

On the basis of embodiment 3, as shown in FIGS. 6 and 7, a suction hole 242 is provided on a portion of the pressing ring 24 facing an end surface of the knife switch observation hole 3. The suction hole 242 is in communication with the fixing cavity 221. An outer surface of the suction hole 242 provided with a sealing ring 243 made of an elastic material.

Specific workflow is as follows: on the basis of the specific workflow in embodiment 3, after the detection camera 1 is mounted on the knife switch observation hole 3, the portion of the pressing ring 24 provided with the suction hole 242 is in close contact with the end surface of the knife switch observation hole 3. When the pressing ring 24 is pushed, the limiting airbag 25 in the pressing ring 24 is compressed, the volume decreases, and the internal space volume of the pressing ring 24 decreases. When the pressing is finished, the end of the pressing ring located in the sliding groove 211 has a reset tendency under the action of the connected return spring, while when the pressing ring 24 is reset, the internal space increases but the air pressure decreases, which requires to supplement airflow from outside through the suction hole 242.

The sealing ring 243 provided on the outer ring surface of the suction hole 242 improves the sealing performance of the suction hole 242, so that it is difficult for external air flow to enter. Therefore, the negative pressure effect of the limiting cavity 241 in the pressing ring 24 makes the suction hole 242 and the end surface of the knife switch observation hole 3 in contact therewith are attracted to each other and be tightly fixed, further ensuring the stable combination between the limiting sleeve 21 and the knife switch observation hole 3. When removing is required, it is only necessary to cause the airflow in the limiting airbag 25 to return, and the expanded limiting airbag 25 will push out the air inside the limiting cavity 241 through the suction hole 242. The negative pressure effect is then released, so that the pressing ring 24 is separated from the end of the knife switch observation hole 3 in contact therewith, facilitating the removal of the detection camera 1 and reducing the damage to the detection camera 1 that may be caused by manual operation.

### Embodiment 5

On the basis of embodiment 4, as shown in FIGS. 6 and 7, a fixing magnet 23 is provided on the outer surface of the limiting snap ring 22 and is located in an inner region of the limiting cavity 241. The fixing magnet 23 is distributed annularly around a central axis of the limiting sleeve 21.

Specific workflow is as follows: on the basis of the specific workflow in embodiment 4, when the monitoring bump 11 is initially embedded into the knife switch observation hole 3 and is not stable, the fixing magnet 23 located on the limiting snap ring 22 of the outer ring of the monitoring bump 11 moves towards the inner wall of the knife switch observation hole 3 due to the magnetic attraction between the fixing magnet 23 and the inner wall of the knife switch observation hole 3, driving the monitoring bump 11 to shake to both sides and collide with the inner wall of the knife switch observation hole 3, which can easily cause damage to various components on the monitoring bump 11. Therefore, in the initial state, the fixing magnet 23 is provided on the upper surface of the limiting snap ring 22 and located in the fixing cavity 221, which can be shielded by the pressing ring 24. The pressing ring 24 can be made of electromagnetic shielding material to limit the magnetic attraction between the fixing magnet 23 and the inner wall of the knife switch observation hole 3.

As the monitoring bump 11 and the limiting snap ring 22 are stably embedded into the knife switch observation hole 3, the sliding of the pressing ring 24 exposes the fixing magnet 23 located on the outer ring surface of the limiting snap ring 22, and the magnetic attraction limit fixing function is exerted. The monitoring bump 11 and the knife switch observation hole 3 maintains stable under the action of the limiting snap ring 22 and the fixing cavity 221. The bulge of the fixing cavity 221 maintains a gap between the exposed fixing magnet 23 and the corresponding inner wall of the knife switch observation hole 3, so that the fixing magnet 23 plays a magnetic fixing role, and the damage caused by collision between the monitoring bump 11 and the inner wall of the knife switch observation hole 3 can be avoided. During the removing process, due to the gap effect, the fixing magnet 23 is not in direct contact with the inner wall of the knife switch observation hole 3, reducing the friction resistance received by the limiting snap ring 22 when sliding away, thereby making the removing of the detection camera 1 more smooth.

### Embodiment 6

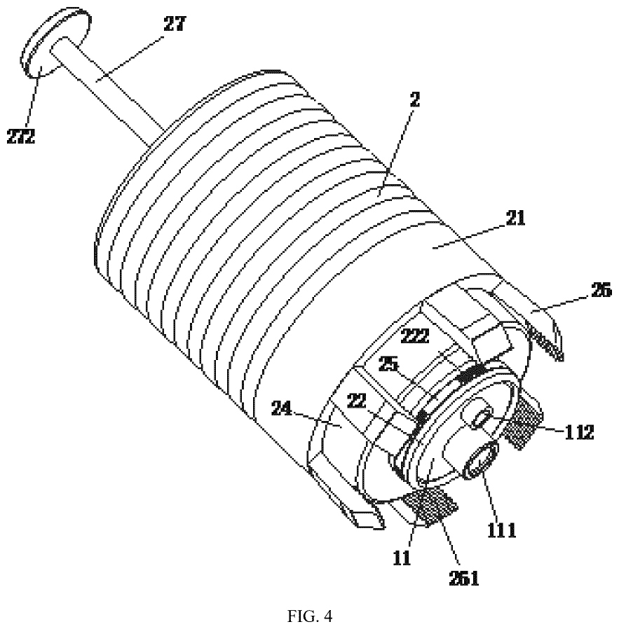

On the basis of the embodiment 5, as shown in FIGS. 4 to 7, a fixing claw 26 is provided at an end of the limiting sleeve 21 and is located outside the pressing ring 24, and the fixing claw 26 is made of an elastic material. Anti-slip blocks 261 are uniformly arranged on an inner surface of the fixing claw 26, and each anti-slip block 261 has a sharp end and is made of a rubber material.

Specific workflow is as follows: based on the specific workflow in embodiment 5, in the initial state, the end of the fixing claw 26 is adjacent to the end of the pressing ring 24. As the pressing ring 24 is retracted under pressure during the installation process, the fixing claw 26 protrudes relative to the end of the knife switch observation hole 3. Since the end of the knife switch observation hole 3 protrudes relative to the closed chamber, the fixing claw 26 which also protrudes is embedded on the outer ring surface of the end of the knife switch observation hole 3. The end of the fixing claw 26 can be provided with a magnet which has a weaker magnetism than that of the fixing magnet 23, so that the end of the fixing claw 26 is adjacent to and in tight contact with the outer ring surface of the end of the knife switch observation hole 3. The anti-slip block 261 will also be in tight contact with the outer ring surface, so that the fixing claw 26 drives the detection camera 1 to engage with the protrusion at the end of the knife switch observation hole 3, further ensuring the limit fixing effect of the detection camera 1.

### Embodiment 7

On the basis of embodiment 6, as shown in FIGS. 1 to 6, a cleaning rod 27 is provided at an end of the limiting sleeve 21 away from the limiting snap ring 22, a cleaning block 271 is provided at an end of the cleaning rod 27. The cleaning block 271 has a circular plate structure, the surface of the cleaning block 271 is less than the cross-section of the camera hole 32 by 2 mm to 3 mm. An outer surface of the cleaning block 271 is wrapped by a cleaning sleeve 272 which is made of chemical fiber or cotton cloth.

Specific workflow is as follows: on the basis of the specific workflow in embodiment 3, external dust may adhere to the corresponding sealing glass in the camera hole 32 due to electrostatic action in an electromagnetic environment. Therefore, before the monitoring operation starts, firstly the limiting sleeve 21 is taken, the cleaning rod 27 on the limiting sleeve 21 is aligned with the knife switch observation hole 3 and is embedded therein. The cleaning liquid is adhered to the surface of the cleaning sleeve 272, and the cleaning liquid can be a special cleaning product for electric-switch equipment to avoid negative impact on the equipment. The cleaning rod 27 is rotated to allow the cleaning sleeve to wipe the surface of the sealing glass and cleans up dust that may adhere thereto, ensuring the cleanliness of the sealing glass, thereby ensuring that the image captured by the detection camera 1 is clear and thus the judgment result is more accurate.

The basic concept, main features and advantages of the present disclosure have been shown and described above. Those skilled in the art should understand that the present disclosure is not limited by the above-described embodiments, and the descriptions in the above-described embodiments and in the specification are only to illustrate the concept of the present disclosure. Various modifications and improvements without departing from the concept of the present disclosure can be made, which should fall within the scope of the present disclosure. The scope of the present disclosure is defined by the appended claims and their equivalents.

1. A portable and handheld device for rapidly detecting a state of GIS equipment, comprising: a detection camera a GIS detection tablet, an image analysis module, a data transmission module, and a fixing and limiting module
wherein an end of the detection camera protrudes to form a monitoring bump the monitoring bump is provided with a camera lens and a fill light the monitoring bump is embedded into a knife switch observation hole the camera lens and the fill light lamp are embedded into an camera hole and a fill light hole of the knife switch observation hole respectively, a protective cover is sleeved on an outside of the monitoring bump;
the data transmission module is configured to transmit an image information captured by the detection camera to the GIS detection tablet, the image analysis module is mounted on the GIS detection tablet, and is configured to analyze the image information and determine a position change of a knife switch to be detected;
the fixing and limiting module is configured to assist the detection camera to be fixed in the knife switch observation hole wherein the fixing and limiting module includes a limiting sleeve and the limiting sleeve is cylindrical and wraps around an outside of the detection camera
an end of the limiting sleeve is provided with a limiting snap ring wrapping around the monitoring bump, an outer surface of the limiting snap ring is provided with a fixing magnet, and an outer ring surface of the limiting snap ring is made of an elastic material.

2. The portable and handheld device for rapidly detecting the state of GIS equipment according to claim 1, wherein a sliding groove is provided on an inner sidewall of the limiting sleeve adjacent to the limiting snap ring, a pressing ring is mounted on an annular opening portion of the limiting sleeve adjacent to the limiting snap ring;
a vertical cross-section of the pressing ring is in an L-shape, one end of the pressing ring is embedded into the sliding groove and is slidably connected to the sliding groove, and another end of the pressing ring is in contact with an outer surface of the limiting snap ring;
a region surrounded between the pressing ring and the limiting snap ring defines a limiting cavity an outer ring portion of the limiting snap ring is hollow and defines a fixing cavity, and the limiting cavity is in communication with the fixing cavity.

3. The portable and handheld device for rapidly detecting the state of GIS equipment according to claim 2, wherein a limiting airbag is provided in the limiting cavity, the limiting airbag is annular, the limiting airbag is in communication with an interior of the fixing cavity via a connecting pipe and a control valve is provided in a middle portion of the connecting pipe

4. The portable and handheld device for rapidly detecting the state of GIS equipment according to claim 3, wherein limiting bumps are uniformly arranged on an outer surface of a side wall of the fixing cavity and an end of each limiting bump is inclined in a direction away from the camera hole.

5. The portable and handheld device for rapidly detecting the state of GIS equipment according to claim 2, wherein a suction hole is provided on a portion of the pressing ring facing an end surface of the knife switch observation hole and the suction hole is in communication with the fixing cavity.

6. The portable and handheld device for rapidly detecting the state of GIS equipment according to claim 5, wherein an outer surface of the suction hole provided with a sealing ring made of an elastic material.

7. The portable and handheld device for rapidly detecting the state of GIS equipment according to claim 2, wherein the fixing magnet is provided on the outer surface of the limiting snap ring and is located in an interior region of the limiting cavity and the fixing magnet is distributed annularly around a central axis of the limiting sleeve.

8. The portable and handheld device for rapidly detecting the state of GIS equipment according to claim 7, wherein a fixing claw is provided at an end of the limiting sleeve and is located outside the pressing ring and the fixing claw is made of an elastic material.

9. The portable and handheld device for rapidly detecting the state of GIS equipment according to claim 8, wherein anti-slip blocks are uniformly arranged on an inner surface of the fixing claw, and each anti-slip block has a sharp end and is made of a rubber material.

10. The portable and handheld device for rapidly detecting the state of GIS equipment according to claim 9, wherein a cleaning rod is provided at an end of the limiting sleeve away from the limiting snap ring a cleaning block is provided at an end of the cleaning rod the cleaning block has a circular plate structure and is wrapped by a cleaning sleeve around an outer surface thereof.
